(19) United States
(12) Patent Application Publication
(10) Pub. No.: US 2021/0098057 A1
(43) Pub. Date: Apr. 1, 2021

(54) SRAM LOW-POWER WRITE DRIVER

(71) Applicant: QUALCOMM Incorporated, San Diego, CA (US)

(72) Inventors: Changho JUNG, San Diego, CA (US); Chulmin JUNG, San Diego, CA (US); Percy DADABHOY, Austin, TX (US)

(21) Appl. No.: 16/911,313

(22) Filed: Jun. 24, 2020

Related U.S. Application Data
(60) Provisional application No. 62/906,678, filed on Sep. 26, 2019.

(51) Int. Cl. G11C 11/419; H03K 3/3562; H04M 1/02

(52) U.S. Cl. CPC G11C 11/419; H04M 1/0202; H03K 3/35625

(57) ABSTRACT

A memory is provided with a pre-charge circuit/write driver that pre-charges a bit line in a bit line pair responsive to a master latch output signal from a master latch in a data buffer. A slave latch associated with the master latch is prevented from becoming open by a clock controller during write operations for the memory.

### CROSS-REFERENCE TO RELATED APPLICATIONS

This application claims priority to and the benefit of U.S. Provisional Patent Application No. 62/906,678 filed Sep. 26, 2019, which is hereby incorporated by reference in its entirety.

### TECHNICAL FIELD

This application relates to memories, and more particularly to a low-power write driver for a static random-access memory (SRAM).

### BACKGROUND

A significant factor for mobile device battery life is the power consumption from the mobile device's embedded memories. For example, it is conventional to pre-charge both bit lines in a bit line pair for each write cycle in an embedded static random-access memory (SRAM). One of the bit lines in the bit line pair is then discharged responsive to the binary value to be written to a bitcell coupled to the bit line pair in the write cycle. The pre-charging and subsequent discharging of the bit lines contributes significantly to the embedded SRAM's dynamic power consumption.

### SUMMARY

A memory is disclosed that includes: a data buffer including a master latch configured to pass a current data bit input signal to provide a master latch output signal while the master latch is open; a clock controller configured to clock the master latch to be open prior to an assertion of a system clock signal and to be closed for a master latch delay period following the assertion of the system clock signal; and a pre-charge circuit configured to pre-charge a bit line in a bit line pair responsive an assertion of the master latch output signal.

A method for a memory is disclosed that includes: prior to an assertion of a system clock signal, pre-charging a first bit line in a bit line pair responsive to a current data bit input signal; following the assertion of the system clock signal, discharging a second bit line in the bit line pair responsive to the current data bit input signal; and writing the current data bit input signal into a bitcell through the pre-charged first bit line and the discharged second bit line.

In addition, a memory is disclosed that includes: a master-slave latch; a clock controller configured to maintain closed a slave latch in the master-slave latch during a write operation for the memory; and a pre-charge circuit configured to pre-charge a first bit line in a bit line pair responsive to master latch output signal from a master latch in the master-slave latch.

Finally, a memory is provided that includes: a master-slave latch including a master latch and a slave latch; a bit line pair including a true bit line and a complement bit line; a clock controller configured during a write operation for the memory to maintain the slave latch closed and to clock the master latch to latch a current data bit signal to form a master latch output signal; a first logic gate configured to invert the master latch output signal; and a first transistor having a source connected to a power supply node, a drain connected to the true bit line, and a gate connected to an output from the first logic gate.

These and additional advantages may be better appreciated through the following detailed description.

### BRIEF DESCRIPTION OF THE DRAWINGS

FIG. 1 illustrates an example memory including a data buffer and a write driver in accordance with an aspect of the disclosure.

FIG. 2 is a circuit diagram of an example data buffer in accordance with an aspect of the disclosure.

FIG. 3 is a circuit diagram of an example write driver in accordance with an aspect of the disclosure.

FIG. 4 is a timing diagram for various waveforms in an example memory in accordance with an aspect of the disclosure.

FIG. 5 is a flowchart for an example method of operation for a memory in accordance with an aspect of the disclosure.

FIG. 6 illustrates some example systems incorporating a memory in accordance with an aspect of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

A memory such as an SRAM is provided with a plurality of bitcells arranged according to rows and columns. Each column has a corresponding pair of bit lines. Each row has a corresponding word line. At each row and column intersection, there is a corresponding one of the bitcells. Write and read operations for the SRAM are controlled by a system clock signal. In a write operation, a master latch in a master-slave latch data buffer latches a data bit prior to the assertion of the system clock signal. The write driver then receives the latched data bit from the master latch in the data buffer and pre-charges the corresponding bit line in the addressed bit line pair.

The resulting pre-charging is denoted herein as an “intelligent” pre-charging because it depends on the data bit input signal. Only one of the bit lines in the bit line pair is pre-charged responsive to the data bit input signal. Thus, if the current data bit input signal is unchanged as compared to a preceding data bit input signal for the same column, the same bit line would be pre-charged in both write operations whereas the remaining bit line would remain discharged for both write operations. As compared to a traditional pre-charging in which both bit lines in a bit line pair are pre-charged, intelligent pre-charging saves power. Although both the use of a master-slave latch data buffer and intelligent pre-charging is known, traditional intelligent pre-charging responded to the latching of the data bit input signal in the slave latch in the data buffer. The slave latch in a traditional data buffer was opened after the system clock signal is asserted. But in the intelligent pre-charging disclosed herein, the slave latch remains closed throughout the system clock signal cycle. The slave latch thus does not waste power latching a master latch output signal that in turn depends upon the data bit input signal. The slave latch is thus only used during a scan mode in which various ones of the data buffers form a scan chain.

Since the disclosed intelligent write driver is driven by a master latch output signal from a master latch in the data buffer, the resulting pre-charging of the corresponding one of the bit lines in a bit line pair occurs prior to the assertion of the system clock signal so that the power is attributed to the particular data pin being asserted and not to the clock pin. The data bit input signal as presented to the data buffer is deemed herein to “toggle” when it changes binary states. The master latch will toggle its master latch output signal accordingly so that the master latch output signal toggles in response to the toggling of the data bit. The intelligent pre-charging responds to the toggling of the master latch output signal so that the bit line that had been discharged in an addressed bit line pair is pre-charged to the memory power supply voltage in response to the toggling of the master latch output signal. The resulting control of the data buffer is quite advantageous as the power consumption from the latching of the data bit input signal within the slave latch is avoided.

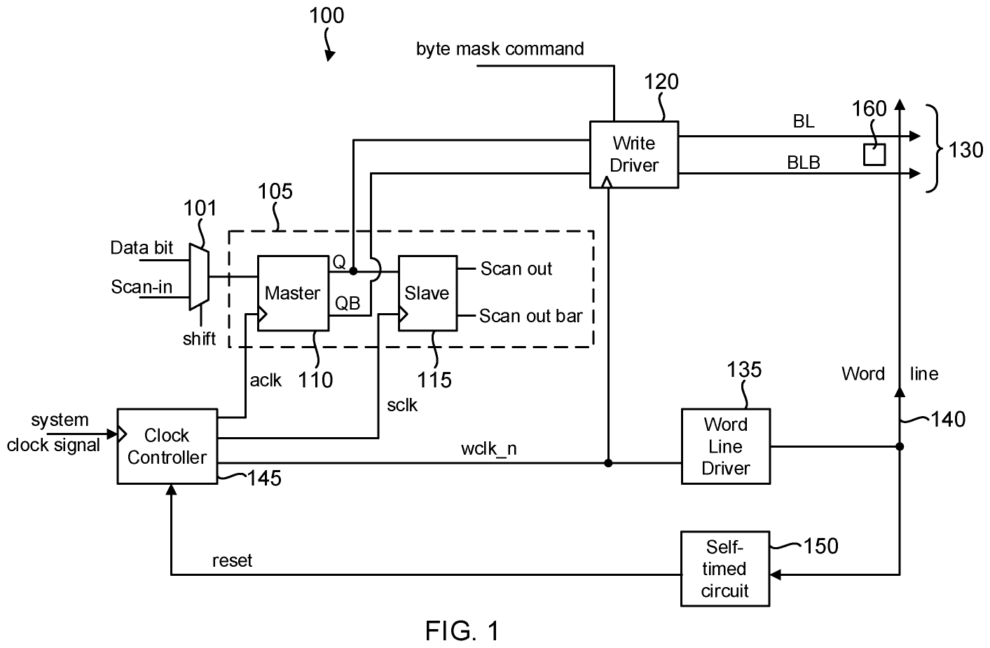

An example memory 100 is shown in FIG. 1. During normal (non-scan) operation, an input multiplexer 101 selects for a data bit input signal to drive a master latch 110 within a master-slave latch data buffer 105. To control whether master latch 110 is open to the data bit input signal, a clock controller 145 responds to a system clock signal to control a master latch clock signal (aclk). Master latch 110 is configured to be open when the master latch clock signal aclk is low (grounded) and to be closed when master latch clock signal aclk is asserted high to a power supply voltage VDD for memory 100. Clock controller 145 is configured to assert the master latch clock signal high in response to an assertion of the system clock signal. Prior to the rising edge of the system clock signal, master latch 110 will thus be open so that the data bit input signal controls the binary state of a Q output signal from master latch 110. With master latch 110 open, the binary state of the Q output signal will equal the binary state for the data bit input signal. Similarly, when master latch 110 is open, a QB output signal from master latch 110 that is the complement of the Q output signal will have the complement binary state of the data bit input signal.

The Q output signal and the QB output signal both drive a write driver 120 to cause write driver 120 to pre-charge a corresponding bit line from a bit line pair 130. For example, if the Q output signal is true, write driver 120 pre-charges a true bit line BL in bit line pair 130 to the memory power supply voltage VDD. Conversely, if the QB output signal is true, write driver 120 pre-charges a complement bit line BLB in bit line pair 130 to the memory power supply voltage VDD. As discussed earlier, such pre-charging is “intelligent” in that the bit line that is to be discharged during the write operation is not pre-charged. For example, if the Q output signal is true, write driver 120 does not pre-charge the complement bit line BLB. Similarly, if the QB output signal is true, write driver 120 does not pre-charge the bit line BL. Bit line pair 130 is also denoted herein as a column for memory 100. Since the pre-charging in write driver 120 is tied to the binary value of the data bit input signal, there is thus no need for a separate pre-charging circuit in write driver 120. In contrast, a traditional write driver would include a pre-charge circuit that pre-charges both bit lines regardless of the binary value for the data bit input signal. Since the pre-charging in write driver 120 is tied to the binary value of the data bit input signal, write driver 120 may also be denoted as a pre-charge circuit since the two functions are inseparable during normal operation.

Write driver 120 may also respond to a byte mask command that masks a byte including the addressed column. If the byte mask command is asserted, write driver 120 pre-charges both bit lines and does not respond to any data bit input signals. The bit lines would thus remain charged while the byte mask command is asserted.

The pre-charging occurs prior to the rising edge of the system clock signal since the pre-charging is triggered by the data bit input signal. In contrast, the discharging of a bit line by write driver 120 is responsive to the assertion of the system clock signal. Prior to this bit line discharge, clock controller 145 responds to the assertion of the system clock signal by asserting a word line clock signal such as an active-low word line clock signal wclk_n to control a word line driver 135. Note that as defined herein, a binary signal is deemed to be asserted if its logical value is true, regardless of whether the signal is an active-high signal or an active-low signal. An active-low signal is thus asserted by being discharged whereas an active-high signal is asserted by being charged to the power supply voltage. Word line driver 135 responds to the low assertion of the word line clock signal wclk_n by charging a word line 140 to the power supply voltage VDD. Write driver 120 also responds to the assertion of the word line clock signal wclk_n by discharging the corresponding bit line in bit line pair 130. For example, if the Q output signal is true, write driver 120 discharges the complement bit line BLB responsive to a falling edge of the word line clock signal wclk_n. Conversely, write driver 120 discharges the bit line BL if the QB output signal is true at the falling edge of the word line clock signal wclk_n.

The assertion of the word line voltage triggers a self-timed clock circuit 150 as is known in the memory arts. Self-timed clock circuit 150 self-times a word line assertion period that is sufficiently long to successfully write the current data bit input signal into a bitcell 160 at an intersection of word line 140 and bit line pair 130. When self-timed clock circuit 150 determines that the word line assertion period is finished, self-timed clock circuit 150 asserts a reset signal to clock controller 145. Clock controller 145 responds to the assertion of the reset signal by de-asserting the word line clock signal wclk_n. In response, word line driver 135 discharges word line 140. Clock controller 145 also responds to the assertion of the reset signal by de-asserting the master clock signal aclk. Master latch 110 is thus closed for a master latch delay period that approximately extends from the assertion of the system clock signal to the assertion of the reset signal. The master latch delay period keeps master latch 110 closed while the write operation takes place. Note that the data bit input signal could change while the word line is asserted. Since write driver 120 toggles the bit lines when the data bit input signal toggles, such a change in the data bit input signal could affect the write operation should master latch 110 be open while the word line is asserted. The master latch delay period thus ensures the fidelity of the resulting write operation.

During normal operation (non-scan mode operation), clock controller 145 maintains a slave latch 115 closed in data buffer 105. To control whether slave latch 115 is open or closed, clock controller 145 controls a slave latch clock signal (sclk). For example, slave latch 115 may be configured to be closed when the slave latch clock signal sclk is discharged and may be configured to be open when the slave latch clock signal sclk is asserted to the power supply voltage VDD. In such an embodiment, clock controller 145 maintains the slave clock signal sclk low to prevent slave latch 115 from responding to the Q output signal from master latch 110. During a scan mode, clock controller 145 asserts the slave clock signal sclk high in response to an assertion of the system clock signal so that slave latch 115 drives a scan-out signal and a complement scan-out signal (scan out bar) accordingly. Slave latch 115 thus does not change the binary state of the scan-out signal and the complement scan-out signal during normal operation. In that regard, note that memory 100 will include a write driver 120 and a data buffer 105 for every column in memory 100. There are typically numerous such columns. The power savings from preventing slave latch 115 from toggling during normal operation in memory 100 is thus quite significant and advantageous.

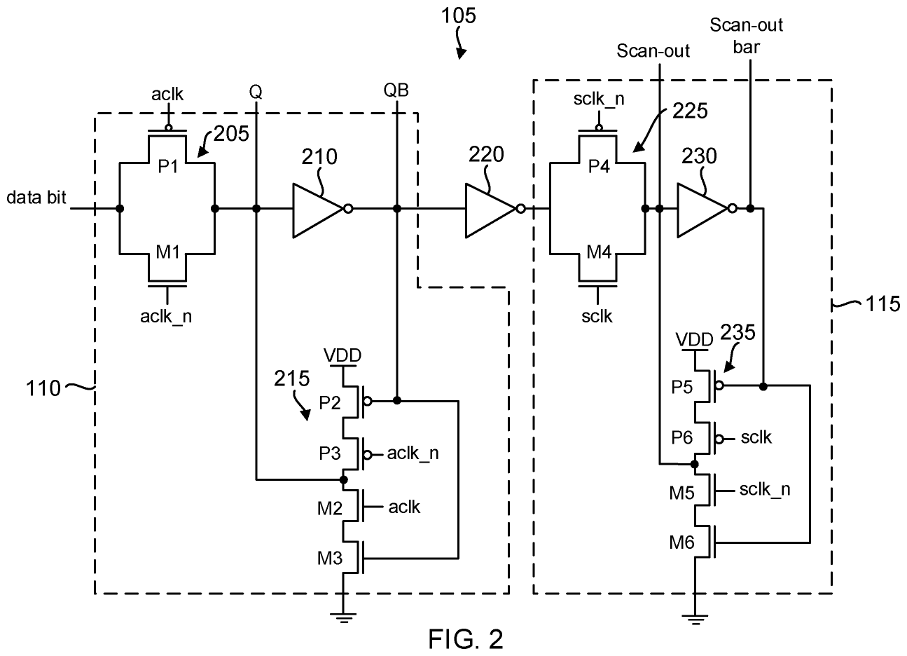

An example data buffer 105 is shown in more detail in FIG. 2. Master latch 110 includes a transmission gate 205 formed by a p-type metal-oxide semiconductor (PMOS) transistor P1 in parallel with an n-type metal-oxide semiconductor (NMOS) transistor M1. The master latch clock signal aclk controls whether transmission gate 205 passes the data bit input signal as selected by input multiplexer 101 (FIG. 1). Multiplexer 101 selects for a scan-in bit during the scan mode of operation. In some embodiments, transmission gate 205 is closed in response to a low state (discharge) for the master latch clock signal aclk. In such an embodiment, the master latch clock signal aclk drives the gate of transistor P1 whereas a complement aclk_n of the master latch clock signal drives the gate of transistor M1. Thus, when the master latch clock signal aclk is low, transmission gate 205 conducts (transmission gate 205 being closed) to pass the data bit input signal to form the Q output signal. An inverter 210 inverts the Q output signal to form the QB output signal. Transmission gate 205 opens (becomes non-conductive) in response to the assertion of the master latch clock signal aclk to prevent any further toggling of the data bit input signal from affecting the Q and QB output signals. Master latch 110 closes in response to the assertion of the master latch clock signal aclk due to the opening of transmission gate 205 and due to the activation of an inverter 215 formed by a PMOS transistor P2 and an NMOS transistor M3. The QB output signal drives the gates of transistors P2 and M3. But the drains of transistors P2 and M3 are coupled to each other through a serial combination of a PMOS transistor P3 and an NMOS transistor M2. The master latch clock signal aclk drives the gate of transistor M2 whereas the complement master latch clock signal aclk_n drives the gate of transistor P3. Transistors P3 and M2 will thus be on when the master latch clock signal aclk is asserted to activate inverter 215. The output of inverter 215 (the drains of transistors P3 and M2) drives the input of inverter 210 to complete the latching of the Q and QB output signals while master latch 110 is closed. As used herein, the term “latch” refers to any suitable storage element that may either be synchronous (e.g., a register or flip-flop) or asynchronous (e.g. a reset-set latch).

The QB output signal as inverted through an inverter 220 forms an input signal for slave latch 115. A transmission gate 225 formed by a parallel combination of a PMOS transistor P4 and a NMOS transistor M4 controls whether the input signal from inverter 220 passes into slave latch 115. The slave latch clock signal sclk drives a gate of transistor M4 whereas a complement of the slave latch clock signal (sclk_n) drives a gate of transistor P4. Transmission gate 225 is thus closed when the slave latch clock signal sclk is low and the complement slave latch clock signal sclk_n is high. During normal operation, clock controller 145 keeps the slave latch clock signal sclk discharged to so that transmission gate 225 is open to prevent slave latch 115 from responding to the Q and QB output signals (slave latch 115 is thus closed when the slave latch clock signal sclk is discharged). During a scan mode of operation, clock controller 145 asserts the slave clock signal sclk in response to the assertion of the system clock signal to close transmission gate 225. The scan-in signal would have been latched in master latch 110 so that the scan-in signal passes through transmission gate 225 to form a scan-out signal. An inverter 230 inverts the scan-out signal to form the complement scan-out signal (scan-out bar). An inverter 235 in slave latch 115 as formed by a PMOS transistor P5 and an NMOS transistor M6 functions analogously to inverter 215 in master latch 110. The complement scan-out signal drives the gates of transistors P5 and M6. But the drains of transistors P5 and M6 are coupled to each other through a serial combination of a PMOS transistor P6 and an NMOS transistor M5. The slave latch clock signal sclk drives the gate of transistor P6 whereas the complement slave latch clock signal sclk_n drives the gate of transistor M5. Transistors P6 and M5 will thus be on when the slave latch clock signal sclk is de-asserted to activate inverter 235. The output of inverter 235 (the drains of transistors P6 and M5) drives the input to inverter 230. Slave latch 115 is thus closed during a scan mode in response to the slave latch clock signal sclk being discharged.

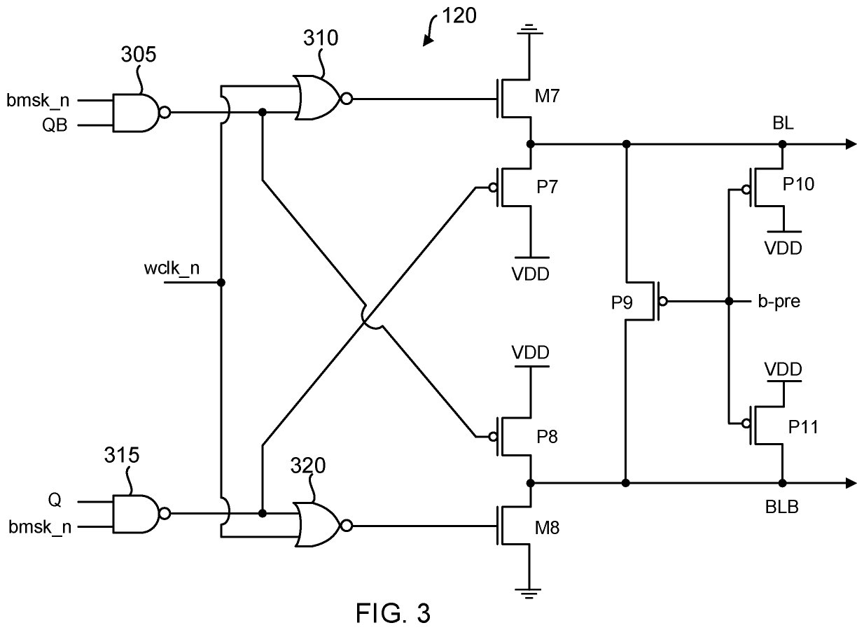

An example write driver 120 is shown in more detail in FIG. 3. A logic gate such as a NAND gate 315 processes the Q output signal and an active-low byte mask command bmsk_n. During normal operation, the byte mask command bmsk_n is de-asserted by being charged to the power supply voltage VDD. NAND gate 315 then functions as an inverter to invert the Q output signal. The output of NAND gate 315 drives a gate of a PMOS transistor P7 having a source connected to a power supply node for the power supply voltage VDD and a drain connected to the bit line BL. Since NAND gate 315 functions as an inverter during normal operation, a true value for the Q output signal is inverted by NAND gate 315 to switch on transistor P7 and pre-charge the bit line BL. Similarly, an output of a NAND gate 305 controls the pre-charging of the complement bit line BLB responsive to the QB output signal. NAND gate 305 NANDs the bit mask signal bmsk_n with the QB output signal to drive a gate of a PMOS transistor P8 having its source connected to the power supply node and having a drain connected to the complement bit line BLB. The complement bit line BLB will thus be pre-charged to the power supply voltage VDD in response to the QB output signal having a logical true value.

To control the discharge of the bit lines, write driver 120 includes a pair of logic gates such as formed by a NOR gate 310 and a NOR gate 320. NOR gate 310 NORs the output of NAND gate 305 and the word line clock signal wclk_n. The output of NOR gate 310 will thus remain de-asserted while the word line clock signal wclk_n is de-asserted to the power supply voltage VDD. When the word line clock signal wclk_n is asserted low (discharged), NOR gate 310 inverts the output of NAND gate 305. The output of NAND gate 305 may also be denoted herein as a first logic gate output signal. If the QB output signal is charged to the power supply voltage VDD during normal operation, the output of NOR gate 310 will thus be asserted to the power supply voltage VDD to switch on a NMOS transistor M7. The output of NOR gate 310 may also be denoted herein as a second logic gate output signal. The source of transistor M7 is connected to ground whereas its drain is connected to the bit line BL. Transistor M7 is thus switched on by the high value for the QB output signal to discharge the bit line BL.

Operation of NOR gate 320 is analogous with respect to NORing the output of NAND gate 315 and the word line clock signal wclk_n. NOR gate 320 drives a gate of an NMOS transistor M8 that has its source connected to ground and a drain connected to the complement bit line BLB. During normal operation, NAND gate 315 inverts an asserted value for the Q output signal into a discharged output signal. When NOR gate 320 NORs the discharged output signal from NAND gate 315 with the asserted low value for the word line clock signal wclk_n, NOR gate 320 drives its output signal high to switch on transistor M8 and discharge the complement bit line BLB.

Should the byte mask signal bmsk_n be asserted low, an active-low byte pre-charge signal b_pre is asserted low in response to an assertion of the system clock signal clk. The byte pre-charge signal b_pre drives a gate of a PMOS transistor P9, a gate of a PMOS transistor P10, and a gate of a PMOS transistor P11. Transistors P10 and P11 both have their sources connected to the power supply node. The drain of transistor P10 connects to bit line BL whereas the drain of transistor P11 connects to complement bit line BLB. The bit lines BL and BLB are thus both pre-charged to the power supply voltage VDD when the byte pre-charge signal b_pre is asserted low. To be ensure that the byte pre-charging is balanced, transistor P9 couples between bit lines BL and BLB.

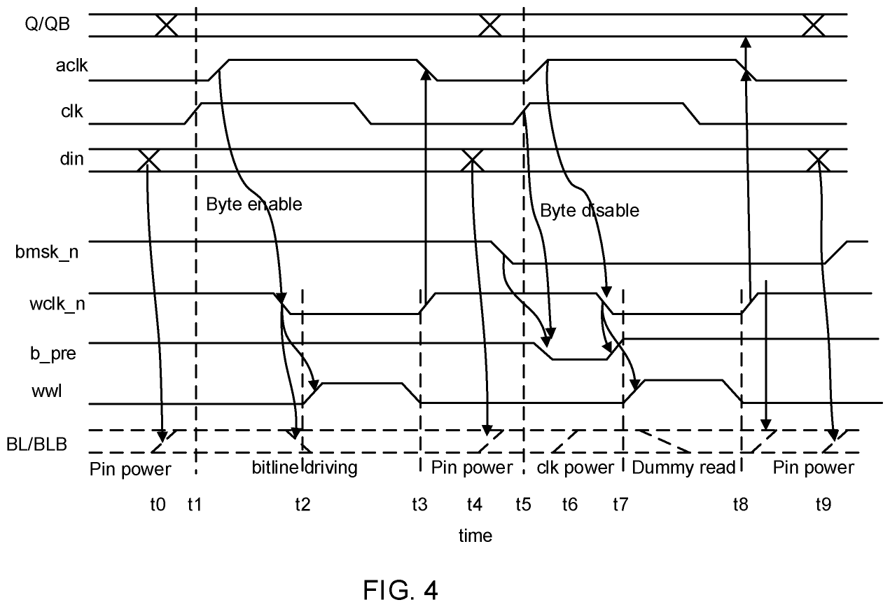

The timing of the bit line pre-charging and discharging may be better appreciated with reference to FIG. 4, which illustrates some bit line voltage waveforms along with several other signals for an example memory. A first system clock signal (clk) cycle begins a time t1 and ends at a time t5. During this initial system clock cycle, the byte mask signal bmsk_n is de-asserted high. Prior to a time t0, the current data bit input signal din is provided to data buffer 105 (FIG. 1). The current data bit input signal din may be either unchanged or be the complement of a previous data bit input signal. Should the current data bit input signal din be the inverse of the previous data bit input signal, either the bit line BL voltage or the complement bit line BLB voltage will be pre-charged from a discharged state to the power supply voltage VDD. Since power must flow from a power supply node to the corresponding bit line for such a pre-charge, the bit line pre-charging at time t0 is denoted as “pin power” in FIG. 4.

The assertion of the system clock signal clk at time t1 causes the master latch clock signal aclk to be asserted high to close master latch 110. The resulting assertion of the master latch clock signal aclk is followed by an assertion low of the word line clock signal wclk_n at a time t2. The assertion low of the word line clock signal wclk_n at time t2 causes the word line voltage wll to be asserted and also triggers the discharge of one of the bit lines. Just as with the pre-charging at time t1, which bit line that is discharged (designated as a bit line driving in FIG. 4) around time t2 depends upon the current data bit input signal din. If the current data bit input signal din is a binary one, it is the bit line voltage BL that is pre-charged at time t0 whereas it is the complement bit line BLB voltage that is discharged at time t2. The complement pre-charge and discharge of the bit line voltages would occur if the current data bit input signal din was a binary zero.

The self-timing for the word line assertion times out at a time t3 so that the word line voltage wwl is discharged and the word line clock signal wclk_n de-asserted to the power supply voltage VDD. The reset of the word line clock signal wclk_n triggers a reset of master latch clock signal aclk. A new data bit input signal din is then presented as a time t4, which triggers a pre-charge of the corresponding one of the bit line voltages. The current write operation is then concluded at time t5.

A subsequent cycle for the system clock signal clk begins at time t5. Prior to this subsequent clock cycle, the byte mask signal bmsk_n is asserted low. The assertion of the system clock signal at time t5 thus triggers an assertion low of the byte pre-charge signal b_pre at a time t6. The resulting pre-charging of the bit line voltages at time t6 is denoted as “clk power” in FIG. 4 since it is responsive to the assertion of the system clock signal at time t5. The master latch clock signal aclk is also asserted at time t6. At a time t7, the word line clock signal wclk_n is asserted low in response to the assertion of the system clock signal at time t5. The assertion of the word line clock signal wclk_n causes the byte pre-charge signal b_pre to be de-asserted high and causes the word line voltage wwl to be asserted. The assertion of the word line voltage wwl causes a dummy read to occur to the bitcell at the intersection of the word line and the addressed column. At a time t8, the word line clock signal wclk_n is de-asserted high so that the word line voltage wwl discharges and so that the master latch clock signal aclk resets. Finally, at a time t9, another data bit input signal din is presented.

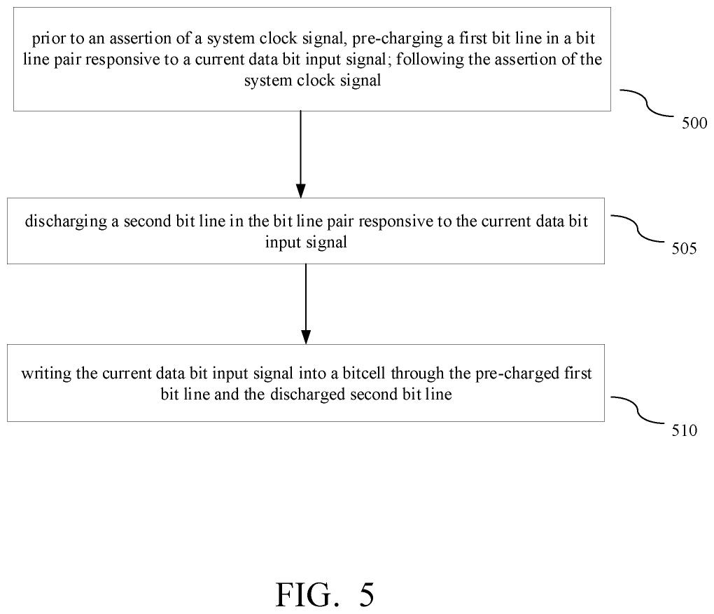

A method of operation for a memory will now be discussed with reference to the flowchart of FIG. 5. The method includes an act 500 of, prior to an assertion of a system clock signal, pre-charging a first bit line in a bit line pair responsive to a current data bit input signal. The pre-charging of either bit line BL or complement bit line BLB responsive to the toggling of the data bit input signal such as at time t0 in FIG. 4 is an example of act 500. The method further includes an act 505 of, following the assertion of the system clock signal, discharging a second bit line in the bit line pair responsive to the current data bit input signal. The discharge of either bit line BL or complement bit line BLB at time t2 in FIG. 4 following the assertion of the system clock signal clk is an example of act 505. Finally, the method includes an act 510 of writing the current data bit input signal into a bitcell through the pre-charged first bit line and the discharged second bit line. The writing to bitcell 160 by write driver 120 through bit line pair 130 is an example of act 510.

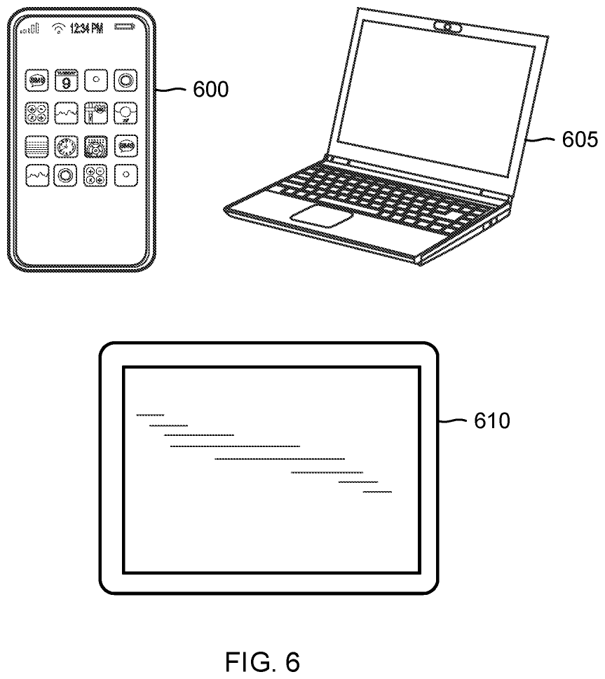

A memory with bit line pre-charging as disclosed herein may be incorporated into a wide variety of electronic systems. For example, as shown in FIG. 6, a cellular telephone 600, a laptop computer 605, and a tablet PC 610 may all include a memory having a pre-charge circuit/write driver in accordance with the disclosure. Other exemplary electronic systems such as a music player, a video player, a communication device, and a personal computer may also be configured with memories constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A memory, comprising:
a data buffer including a master latch configured to pass a current data bit input signal to provide a master latch output signal while the master latch is open;
a clock controller configured to clock the master latch to be open prior to an assertion of a system clock signal and to be closed for a master latch delay period following the assertion of the system clock signal; and
a pre-charge circuit configured to pre-charge a bit line in a bit line pair responsive an assertion of the master latch output signal.

2. The memory of claim 1, wherein the master latch is further configured to invert the current data bit input signal to provide a master latch complement output signal while the master latch is open, and wherein the pre-charge circuit is further configured to discharge a complement bit line in the bit line pair responsive to the assertion of the system clock signal while the master latch complement output signal is grounded.

3. The memory of claim 2, wherein the pre-charge circuit includes:
a first logic gate configured to process the master latch output signal to provide a first logic gate output signal, and
a first transistor configured to switch on to pre-charge the bit line responsive to a discharge of the first logic gate output signal.

4. The memory of claim 3, wherein the clock controller is further configured to assert a word line clock signal responsive to the assertion of the system clock signal.

5. The memory of claim 4, wherein the pre-charge circuit further comprises:
a second logic gate configured to process the word line clock signal with the first logic gate output signal to provide a second logic gate output signal; and
a second transistor configured to switch on to discharge the complement bit line responsive to an assertion of the second logic gate output signal.

6. The memory of claim 5, wherein the second logic gate comprises a NOR gate.

7. The memory of claim 5, wherein the first logic gate is configured to invert the master latch output signal to form the first logic gate output signal.

8. The memory of claim 7, wherein the first logic gate comprises a NAND gate.

9. The memory of claim 1, wherein the data buffer further comprises a slave latch, and wherein the clock controller is further configured to clock the slave latch so that the slave latch is closed during a write operation mode for the memory.

10. The memory of claim 2, wherein the pre-charge circuit is further configured to pre-charge both the bit line and the complement bit line responsive to an assertion of a byte mask signal.

11. The memory of claim 4, further comprising:
a word line driver configured to assert a voltage for a word line responsive to an assertion of the word line clock signal.

12. The memory of claim 11, further comprising:
a self-timed circuit configured to time a word line assertion period responsive to the assertion of the word line clock signal, wherein the clock controller is further configured to de-assert the word line clock signal responsive to an expiration of the word line assertion period.

13. The memory of claim 9, wherein the clock controller is further configured to clock the slave latch to latch a scan-out signal during a scan mode for the memory.

14. The memory of claim 1, wherein the memory is integrated into a cellular telephone.

15. A method, comprising:
prior to an assertion of a system clock signal, pre-charging a first bit line in a bit line pair responsive to a current data bit input signal;
following the assertion of the system clock signal, discharging a second bit line in the bit line pair responsive to the current data bit input signal; and
writing the current data bit input signal into a bitcell through the pre-charged first bit line and the discharged second bit line.

16. The method of claim 15, wherein the pre-charging of the first bit line comprises the pre-charging of a true bit line responsive to the current data bit input signal having a binary one value.

17. The method of claim 15, wherein the pre-charging of the first bit line comprises the pre-charging of a complement bit line responsive to the current data bit input signal having a binary zero value.

18. The method of claim 15, wherein the pre-charging of the first bit line further comprises:
controlling a master latch to be open prior to the assertion of the system clock signal while maintaining a slave latch to be closed;
passing a data bit through the master latch while the master latch is open to form a master latch output signal;
pre-charging the first bit line responsive to the master latch output signal.

19. The method of claim 18, further comprising:
closing the master latch responsive to the assertion of the system clock signal; and
keeping the slave latch closed following the assertion of the system clock signal.

20. A memory, comprising:
a master-slave latch;
a clock controller configured to maintain closed a slave latch in the master-slave latch during a write operation for the memory; and
a pre-charge circuit configured to pre-charge a first bit line in a bit line pair responsive to a master latch output signal from a master latch in the master-slave latch.

21. The memory of claim 20, wherein the memory is integrated with a cellular telephone.

22. The memory of claim 20, wherein the pre-charge circuit is further configured to discharge a second bit line in the bit line pair following an assertion of a system clock signal.

23. A memory, comprising:
a master-slave latch including a master latch and a slave latch;
a bit line pair including a true bit line and a complement bit line;
a clock controller configured during a write operation for the memory to maintain the slave latch closed and to clock the master latch to latch a current data bit signal to form a master latch output signal;
a first logic gate configured to invert the master latch output signal; and
a first transistor having a source connected to a power supply node, a drain connected to the true bit line, and a gate connected to an output from the first logic gate.

24. The memory of claim 23, wherein the first transistor is a first PMOS transistor, the memory further comprising:
a second logic gate configured to invert a complement of the master latch output signal; and
a second PMOS transistor having a source connected to the power supply node, a drain connected to the complement bit line, and a gate connected to an output from the second logic gate.

25. The memory of claim 24, wherein the first logic gate and the second logic gate both comprise a NAND gate.

26. The memory of claim 23, wherein the clock controller is further configured to clock the slave latch during a scan mode of operation for the memory.

27. The memory of claim 23, wherein the clock controller is further configured to clock the master latch during the write operation responsive to an assertion of a system clock.
